(19) United States
(12) Patent Application Publication
(10) Pub. No.: US 2015/0160312 A1
(43) Pub. Date: Jun. 11, 2015

(54) RF LENSES FOR SINGLE-SIDED MAGNETIC IMAGING APPLICATIONS

(71) Applicant: WEINBERG MEDICAL PHYSICS LLC, Bethesda, MD (US)

(72) Inventor: Irving N. WEINBERG, Bethesda, MD (US)

(21) Appl. No.: 14/567,627

(22) Filed: Dec. 11, 2014

Related U.S. Application Data
(60) Provisional application No. 61/914,488, filed on Dec. 11, 2013.

(51) Int. Cl. G01R 33/34; G01R 33/48

(52) U.S. Cl. CPC G01R 33/34; G01R 33/48

(57) ABSTRACT

An apparatus and method perform imaging at a distance that is not immediately adjacent from the face of a single-sided magnetic imaging instrument held adjacent to a sample, where the volume of interest is not adjacent to the magnetic imaging instrument.

### CROSS REFERENCE

This application claims priority under 35 U.S.C. 119(e) U.S. Provisional Patent Application 61/914,488 filed by I. N. Weinberg (incorporated by reference in its entirety).

### FIELD OF THE INVENTION

Disclosed embodiments are directed to Magnetic Resonance Imaging (MRI) instruments as well as electron-spin resonance imaging, magnetic particle imaging or other particle imaging instruments.

### BACKGROUND

Single-sided MRI and NMR devices have been developed for imaging nearby portions of objects. In the 2011 article by W-H Chang et al (entitled “Simple mobile single-sided NMR apparatus with a relatively homogeneous B0 distribution”, published in the journal Magnetic Resonance Imaging, volume 29, pages 869-876, incorporated by reference), the region of interest is about 8-mm from the face of the instrument.

In the 2008 article by J. L. Paulsen et al (entitled “Volume-selective magnetic resonance imaging using an adjustable, single-sided, portable sensor”, published in the journal PNAS, volume 105(52), pages 20601-20604, incorporated by reference), the sensitive volume is about 1 cm from the face of the instrument.

A limiting factor in imaging structures that are farther away from the face of the instrument is the sensitivity of the antenna structure used to collect radio frequency (RF) energy emanating from the object to be imaged. A so-called volume coil has relatively uniform sensitivity throughout its enclosed volume, but would restrict use of a single-sided MRI (since the coil would need to be on multiple sides of an object to work. A so-called surface coil (as used by Chang and Paulsen in their reports) would be compatible with the single-sided approach, but the sensitivity falls off rapidly at a distance from the coil face.

Nevertheless, single-sided MRI would be useful clinically for patients who are claustrophobic and for examination of body parts that are relatively superficial in location.

### SUMMARY

Disclosed embodiments address the need for imaging at a distance that is not immediately adjacent from the face of a single-sided magnetic imaging instrument held adjacent to a sample, where the volume of interest is not adjacent to the magnetic imaging instrument.

### BRIEF DESCRIPTION OF THE FIGURES

The detailed description particularly refers to the accompanying FIGURES in which

FIG. 1 illustrates a representation of equipment for performing single-sided MRI.

### DETAILED DESCRIPTION

Disclosed embodiments address the need for imaging at a distance that is not immediately adjacent from the face of a single-sided magnetic imaging instrument held adjacent to a sample, where the volume of interest is not adjacent to the magnetic imaging instrument.

It is known that metamaterial lenses can be constructed that focus RF energy at a distance from the lens. These metamaterial lenses may be fabricated of many small rings and discrete capacitors, as in the 2008 publication by M. J. Freire et al (entitled “Experimental demonstration of a mu=−1 metamaterial lens for magnetic resonance imaging”, published in the Journal Applied Physics Letters, volume 93, pages 231108, incorporated by reference). In that article, M. J. Freire et al showed that it was possible to focus the sensitivity of the RF at a distance equal to 2*d from the coil face, where “d” is the width of the lens.

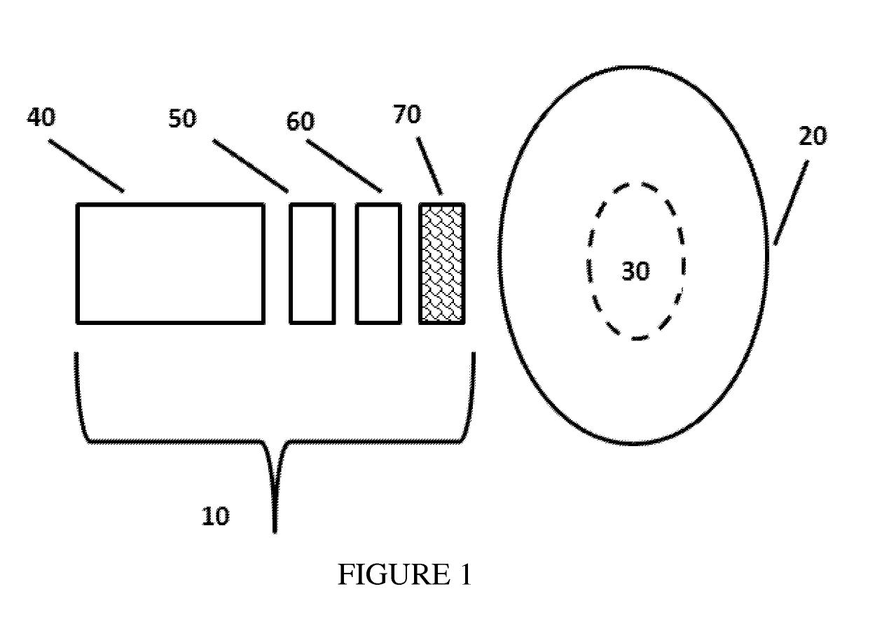

FIG. 1 illustrates a representation of one embodiment of the invention which addresses the need for imaging at a distance that is not immediately adjacent from the face of the single-sided magnetic imaging instrument 10 held adjacent to a sample 20, where the volume of interest 30 is not adjacent to the magnetic imaging instrument.

In the represented embodiment, the illustrated sample 20 may be a part of the body of a subject, be it human or otherwise. In the represented embodiment, the magnetic imaging instrument 10 may utilize magnetic resonance of protons. Thus, the instrument 10 can be fairly characterized as a Magnetic Resonance Imaging (MRI) instrument. However, the invention also applies to other magnetic imaging instruments, for example electron-spin resonance imaging, or magnetic particle imaging or other particle imaging, in which RF energy is also deposited into and received from a volume-of-interest in a sample.

The single-sided MRI instrument 10 polarizes spins in the sample 20, for example, using a static magnetic field from a permanent magnet or electromagnet. Thus, a controllable electromagnetic field source 40 is provided (which includes a controller that enables, automatic, semi-automatic and/or manual control of a static magnectic field). The instrument also includes gradient coil or coils 50 (which is also under control of a controller that enables, automatic, semi-automatic and/or manual control of the gradient to produce a magnetic gradient in the volume-of-interest 30 within the sample using at least one coil driver). The instrument 10 further comprises a coil or coils 60 for transmitting and/or receiving RF energy into and from the volume-of-interest. Further, a metamaterial lens 70 that focuses the RF energy from a location at a distance from the single-sided MRI instrument 10. The metamaterial lens 70 may be made of small rings and discrete capacitors, or may use mutual capacitance between conductive structures, as has been used in so-called millipede coils (U.S. Pat. No. 6,285,189, by W. H. Wong, herein incorporated by reference).

One or more of the set of gradient, transmit, receive, and metamaterial coils may co-exist in the same volume, being fabricated through additive manufacturing processes, as envisioned by W. Peter et al in US Patent Application 20120092105, entitled “Flexible methods of fabricating electromagnets and resulting electromagnet elements,” incorporated herein by reference.

It should be understood that control and cooperation of the components of the instrument 10 may be provided using software instructions that may be stored in a tangible, non-transitory storage device such as a non-transitory computer readable storage device storing instructions which, when executed on one or more programmed processors, carry out a method of imaging the volume of interest within the sample. In this case, the term non-transitory is intended to preclude transmitted signals and propagating waves, but not storage devices that are erasable or dependent upon power sources to retain information.

Accordingly, it should be understood that the disclosed embodiments also encompass a method of operating the disclosed instrument wherein a magnet field source and at least one coil under control of a control unit are used to establish a magnetic field and magnetic gradient, radio frequency energy is generated and transmitted into and received from the sample under the control of the control unit to obtain imaging data regarding the sample, and the volume of the generated RF energy is displaced away from the coil generating the radio frequency energy to be transmitted.

Although not specifically illustrated, it should be understood that the components illustrated in FIG. 1 and their associated functionality may be implemented in conjunction with, or under the control of, one or more general purpose computers running software algorithms to provide the presently disclosed functionality and turning those computers into specific purpose computers.

Moreover, those skilled in the art will recognize, upon consideration of the above teachings, that the above exemplary embodiments may be based upon use of one or more programmed processors programmed with a suitable computer program. However, the disclosed embodiments could be implemented using hardware component equivalents such as special purpose hardware and/or dedicated processors. Similarly, general purpose computers, microprocessor based computers, micro-controllers, optical computers, analog computers, dedicated processors, application specific circuits and/or dedicated hard wired logic may be used to construct alternative equivalent embodiments.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments of the present invention. Such alternative storage devices should be considered equivalents.

While certain illustrative embodiments have been described, it is evident that many alternatives, modifications, permutations and variations will become apparent to those skilled in the art in light of the foregoing description. While illustrated embodiments have been outlined above, it is evident that many alternatives, modifications and variations will be apparent to those skilled in the art. Accordingly, the various embodiments of the invention, as set forth above, are intended to be illustrative, not limiting. Various changes may be made without departing from the spirit and scope of the invention.

As a result, it will be apparent for those skilled in the art that the illustrative embodiments described are only examples and that various modifications can be made within the scope of the invention as defined in the appended claims

1. An imaging instrument apparatus for performing magnetic imaging of a sample, the apparatus comprising:
a magnet field source;
at least one coil under the control of a control unit to establish a magnetic gradient;
at least one coil under the control of the control unit to generate, transmit and receive radio frequency energy into and from the sample to obtain imaging data regarding the sample; and
a radio frequency lens that displaces the volume of transmitted or received RF energy away from the edge of the at least one coil generating, transmitting and receiving radio frequency energy.

2. The apparatus of claim 1, wherein the imaging instrument is sensitive to protons in the sample.

3. The apparatus of claim 1, wherein the imaging instrument is sensitive to electrons in the sample.

4. The apparatus of claim 1, wherein the imaging instrument is sensitive to particles containing a magnetizable material in the sample.

5. The apparatus of claim 1, where the imaging instrument is sensitive to particles in the sample that emit RF energy.

6. The apparatus of claim 1, wherein the magnetic field source is a permanent magnet.

7. The apparatus of claim 1, wherein the magnetic field source is at least one electromagnet.

8. The apparatus of claim 1, further comprising at least one coil driver coupled to the at least one coil and driving the at least one coil to generate a magnetic field gradient.

9. An imaging method for performing magnetic imaging of a sample, the method comprising:
utilizing a magnet field source and at least one coil under control of a control unit to establish a magnetic field and magnetic gradient;
generating, transmitting and receiving radio frequency energy into and from the sample under the control of the control unit to obtain imaging data regarding the sample; and
displacing the volume of transmitted RF energy away from the edge of the at least one coil generating, transmitting and receiving radio frequency energy using a radio frequency lens.

10. The method of claim 9, wherein the imaging data map the sample in terms of the protons present in the sample.

11. The method of claim 9, wherein the imaging data map the sample in terms of the electrons present in the sample.

12. The method of claim 9, wherein the imaging data map the sample in terms of particles containing a magnetizable material in the sample.

13. The method of claim 9, where the imaging data map the sample in terms of particles in the sample that emit RF energy.

14. The method of claim 9, wherein the magnetic field source is a permanent magnet.

15. The method of claim 9, wherein the magnetic field source is at least one electromagnet.

16. The method of claim 9, further comprising at least one coil driver coupled to the at least one coil and driving the at least one coil to generate a magnetic field gradient.
